(19) United States
(12) Patent Application Publication
(10) Pub. No.: US 2026/0090411 A1
(43) Pub. Date: Mar. 26, 2026

(54) SEMICONDUCTOR PACKAGE AND METHOD FOR MANUFACTURING THE SAME

(71) Applicant: SAMSUNG ELECTRONICS CO., LTD., SUWON-SI (KR)

(72) Inventors: Min Jun BAE, Suwon-si (KR); Jong Youn KIM, Suwon-si (KR); Myeong Han BAE, Suwon-si (KR); Min Young LEE, Suwon-si (KR)

(21) Appl. No.: 19/189,492

(22) Filed: Apr. 25, 2025

(30) Foreign Application Priority Data
Sep. 23, 2024 (KR) 10-2024-0128540

(51) Int. Cl. H01L 23/538; H01L 23/14; H01L 23/31; H01L 25/00; H01L 25/18; H10B 80/00

(52) U.S. Cl. CPC H10W 70/611; H10W 74/111; H10W 90/00; H10W 90/401; H10B 80/00; H10W 70/698

(57) ABSTRACT

A semiconductor package includes: a redistribution layer including an upper surface and a lower surface opposite to each other in a first direction; a semiconductor chip disposed on the upper surface of the redistribution layer; a bridge die disposed on the lower surface of the redistribution layer, and electrically connected to the semiconductor chip, wherein the bridge die includes a first surface and a second surface, wherein the first surface faces the semiconductor chip, and the second surface is opposite to the first surface in the first direction; a mold film disposed on a third surface of the bridge die; and a protective film disposed on the second surface of the bridge die.

### CROSS-REFERENCE TO RELATED APPLICATION

This application claims priority under 35 USC § 119 to Korean Patent Application No. 10-2024-0128540 filed on Sep. 23, 2024 in the Korean Intellectual Property Office, the disclosure of which is incorporated by reference herein in its entirety.

### TECHNICAL FIELD

Embodiments of the present inventive concept relate to a semiconductor package and a method for manufacturing the same.

### DISCUSSION OF THE RELATED ART

As wafer fabrication technology advances and semiconductor chips increase in size, chiplet technology is becoming increasingly important. In this approach, semiconductor chips are manufactured separately based on their specific node or function, rather than as a single monolithic chip. This method may help increase wafer yield.

In the chiplet technology, UCIe (Universal Chiplet Interconnect Express) is used for an interface between the semiconductor chips. In this regard, a bridge die may be used as the UCIe. However, since an exposed bridge die is susceptible to cracking, a method for lowering the risk of cracks of the bridge die is desirable.

### SUMMARY

According to embodiments of the present inventive concept, a semiconductor package includes: a redistribution layer including an upper surface and a lower surface opposite to each other in a first direction; a semiconductor chip disposed on the upper surface of the redistribution layer; a bridge die disposed on the lower surface of the redistribution layer, and electrically connected to the semiconductor chip, wherein the bridge die includes a first surface and a second surface, wherein the first surface faces the semiconductor chip, and the second surface is opposite to the first surface in the first direction; a mold film disposed on a third surface of the bridge die; and a protective film disposed on the second surface of the bridge die.

According to embodiments of the present inventive concept, a semiconductor package includes: a first redistribution layer including an upper surface and a lower surface opposite to each other in a first direction; a first semiconductor chip disposed on the upper surface of the first redistribution layer; a second semiconductor chip disposed on the upper surface of the first redistribution layer and spaced apart from the first semiconductor chip in a second direction; a first mold film disposed on the upper surface of the first redistribution layer and covering the first semiconductor chip and the second semiconductor chip; a second redistribution layer disposed on the first mold film; a third semiconductor chip disposed on the second redistribution layer; a bridge die disposed on the lower surface of the first redistribution layer and connected to the first and second semiconductor chips, wherein the bridge die includes a first surface and a second surface, wherein the first surface faces the lower surface of the first redistribution layer, and the second surface is opposite the first surface of the bridge die in the first direction; a second mold film covering a side surface of the bridge die, wherein the second mold film includes a first surface and a second surface, wherein the first surface of the second mold film faces the lower surface of the redistribution layer, and the second surface of the second mold film is opposite the first surface of the second mold film in the first direction; and a protective film covering the second surface of the bridge die and the second surface of the second mold film.

According to embodiments of the present inventive concept, a semiconductor package includes: a redistribution layer including an upper surface and a lower surface opposite to each other in a first direction; a semiconductor chip disposed on the upper surface of the redistribution layer; a bridge die disposed on the lower surface of the redistribution layer, and electrically connected to the semiconductor chip, wherein the bridge die includes a first surface, a second surface opposite to the first surface, and a plurality of side surfaces connecting the first surface and the second surface to each other, wherein the first surface faces the semiconductor chip; a mold film disposed on the plurality of side surfaces of the bridge die; and a protective film disposed on the second surface of the bridge die.

According to embodiments of the present inventive concept, a method for manufacturing a semiconductor package includes: disposing a plurality of bridge dies on a carrier substrate, wherein each of the plurality of bridge dies includes a side surface and an upper surface; forming a mold film on the carrier substrate and the side surface and the upper surface of each of the plurality of bridge dies; removing the carrier substrate; removing a portion of the mold film by using a back-grinding process such that the upper surface of each of the plurality of bridge dies is exposed; flipping the plurality of bridge dies and attaching a protective film to the upper surfaces of the plurality of bridge dies; and separating the plurality of bridge dies from each other by using a sawing process.

In an embodiment of the presentive concept, the side surface of each of the plurality of bridge dies that is formed from the separation of the plurality of dies is covered with the mold film, and the upper surface of each of the plurality of bridge dies is covered with the protective film.

In an embodiment of the presentive concept, the method further includes forming a plurality of connection members on the bridge die.

### BRIEF DESCRIPTION OF DRAWINGS

The above and other aspects and features of the present inventive concept will become more apparent by describing in detail embodiments thereof with reference to the attached drawings, in which:

FIG. 1 is an example plan view illustrating a semiconductor package according to embodiments of the present inventive concept.

FIG. 2 is a cross-sectional view taken along a line A-A of FIG. 1.

FIG. 3 is an enlarged view of a P portion of FIG. 2.

FIG. 4 and FIG. 5 are perspective views for illustrating a bridge die of FIG. 2.

FIG. 6 is a diagram illustrating a semiconductor package according to embodiments of the present inventive concept.

FIG. 7 is a diagram illustrating a semiconductor package according to embodiments of the present inventive concept.

FIGS. 8, 9, 10, 11, 12, 13, 14, 15, 16, 17, and 18 are diagrams illustrating a method for manufacturing a semiconductor package according to embodiments of the present inventive concept.

FIGS. 19, 20, 21, 22, 23, 24, 25 and 26 are diagrams illustrating a method for manufacturing a semiconductor package according to embodiments of the present inventive concept.

### DETAILED DESCRIPTIONS OF THE EMBODIMENTS

Although terms such as first, second, upper, and lower are used herein to describe various elements or components, it is obvious that these element or components are not limited by the terms. Rather, the terms are merely used herein to distinguish one element or component from another element or component. Therefore, it is obvious that a first element or component as mentioned below may also be a second element or component within the technical spirit of the present inventive concept. Further, spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, in the example, terms “below” and “beneath” may encompass both an orientation of above, below and beneath. The device may be otherwise oriented (e.g., rotated 90 degrees or at other orientations) and the spatially relative descriptors used herein may be interpreted accordingly..

In the following description, singular expressions include plural expressions unless the context clearly dictates otherwise.

Hereinafter, embodiments of the present inventive concept are described in detail with reference to the attached drawings. The same reference numerals are used for the same components in the drawings, and duplicate descriptions thereof are omitted or briefly discussed.

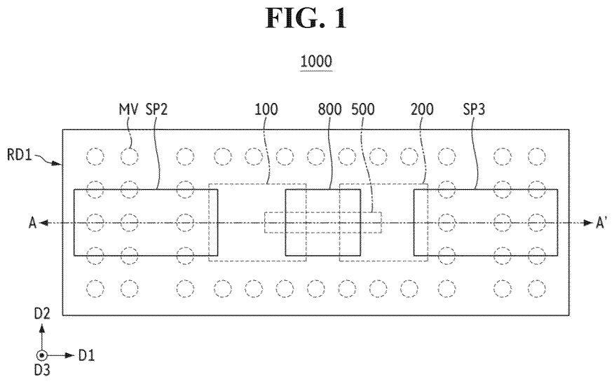

Hereinafter, a semiconductor package according to embodiments of the present inventive concept is described with reference to FIGS. 1 to 5.

Embodiments of the present inventive concept relate to a semiconductor package and a method for manufacturing the same, specifically focusing on increasing reliability in semiconductor packaging by reducing the risk of cracks in a bridge die. As semiconductor chip sizes increase and chiplet technology advances, Universal Chiplet Interconnect Express (UCIe) is commonly used for communication between chips. However, when a bridge die is exposed in a conventional package, it is susceptible to cracking, which can lead to failures. To address this issue, the embodiments of the present inventive concept introduce a protective structure around the bridge die to increase durability and reliability.

According to embodiments of the present inventive concept, the semiconductor package includes a redistribution layer with a semiconductor chip on its upper surface and a bridge die on its lower surface. To protect the bridge die from external stress, a mold film may be provided on the side surfaces of the bridge die and a protective film on its bottom surface. For example, this structure may ensure that the bridge die is fully enclosed, preventing mechanical damage and increasing package longevity. In embodiments of the present inventive concept, the package may also include multiple sub-packages, such as memory chips stacked on logic chips, further increasing functionality in a Package on Package (PoP) architecture.

According to embodiments of the present inventive concept, the manufacturing process of this semiconductor package includes the formation of mold and protective films around the bridge die before it is assembled into the package. The bridge die may be initially placed on a carrier substrate, encapsulated with a mold film, and then subjected to back grinding to expose its top surface. Afterward, the protective film may be attached to its exposed surface, and the individual bridge dies may be separated by using a sawing process. This method may ensure that each bridge die remains fully protected before being incorporated into the final semiconductor package.

Overall, embodiments of the present inventive concept provide a more robust semiconductor package that minimizes crack risks in bridge dies, thereby increasing manufacturing yield, reliability, and performance. By shielding the bridge die from stress and mechanical damage, the package may achieve increased structural integrity.

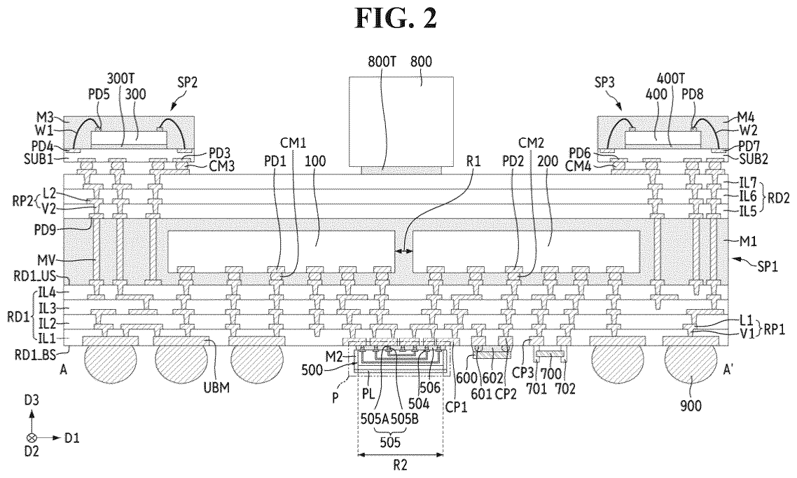

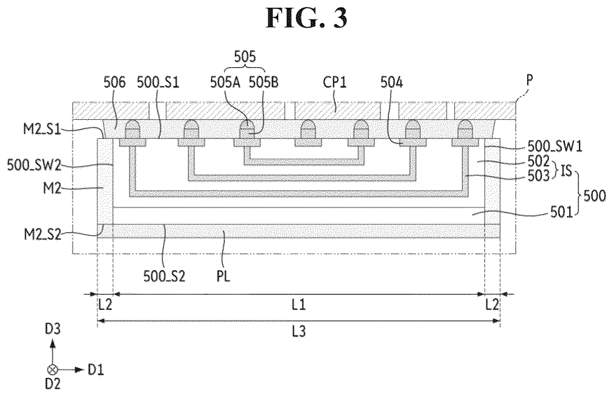

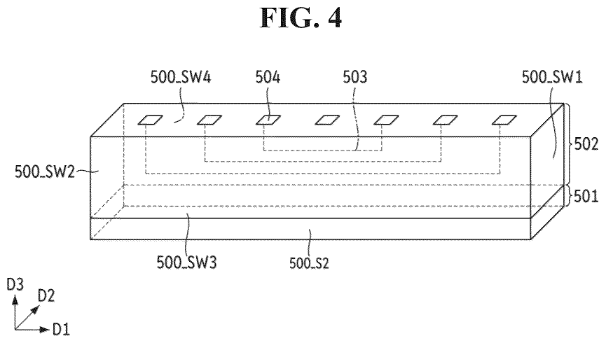

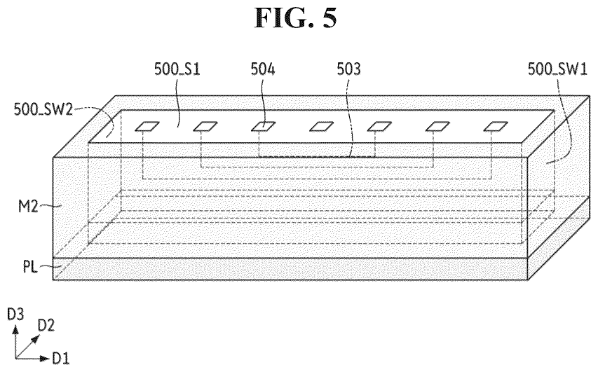

FIG. 1 is an example plan view illustrating a semiconductor package according to embodiments of the present inventive concept. FIG. 2 is a cross-sectional view taken along a line A-A of FIG. 1. FIG. 3 is an enlarged view of a P portion of FIG. 2. FIG. 4 and FIG. 5 are perspective views for illustrating a bridge die of FIG. 2.

Referring to FIGS. 1 to 5, a semiconductor package 1000 may include a first sub-semiconductor package SP1, a second sub-semiconductor package SP2, a third sub-semiconductor package SP3, a bridge die 500, a connection terminal 900, and an HPB (Heat Path Block) 800.

The first sub-semiconductor package SP1 may include a first redistribution layer RD1, a first semiconductor chip 100, a second semiconductor chip 200, a plurality of molding vias MV, a first mold film M1, a second redistribution layer RD2, the bridge die 500, a second mold film M2, a protective film PL, the connection terminal 900, and passive elements 600 and 700. The components of the first sub-semiconductor package SP1 as listed above are merely examples. According to an embodiment of the present inventive concept, the first sub-semiconductor package SP1 may include other components in addition to the components as listed above.

In the present disclosure, a first direction D1, a second direction D2, and a third direction D3 may intersect each other. For example, the first direction D1, the second direction D2, and the third direction D3 may be substantially perpendicular to each other.

The first redistribution layer RD1 may extend in the first direction D1 and the second direction D2. The first redistribution layer RD1 may include an upper surface RD1_US and a lower surface RD1_BS that are opposite to each other in the third direction D3. In the present disclosure, the upper surface RD1_US may be referred to as a first surface, and the lower surface RD1_BS may be referred to as a second surface.

The first redistribution layer RD1 may include redistribution insulating films IL1, IL2, IL3, and IL4 and first redistribution patterns RP1. In FIG. 2, four redistribution insulating films IL1, IL2, IL3, and IL4 are illustrated. However, this is only an example, and the present inventive concept is not limited thereto. The number of redistribution insulating films IL1, IL2, IL3, and IL4 may be one or two or more.

The first redistribution insulating film IL1 may be a layer disposed at the lowest level among the plurality of redistribution insulating films IL1, IL2, IL3, and IL4 included in the first redistribution layer RD1.

The first redistribution insulating film IL1 may include an insulating polymer or a photo-imageable dielectric (PID). For example, the photo-imageable polymer may include at least one of a photo-imageable polyimide, polybenzoxazole (PBO), a phenol-based polymer, or a benzocyclobutene-based polymer.

The first redistribution insulating film IL1 may include an under bump pattern UBM, a first connection pattern CP1, a second connection pattern CP2, and a third connection pattern CP3.

The under bump pattern UBM, the first connection pattern CP1, the second connection pattern CP2, and the third connection pattern CP3 may be disposed within the first redistribution insulating film IL1. The under bump pattern UBM, the first connection pattern CP1, the second connection pattern CP2, and the third connection pattern CP3 may be used to electrically connect the first redistribution layer RD1 to other components. For example, the components disposed on the lower surface RD1_BS of the first redistribution layer RD1 may be connected to the under bump pattern UBM, the first connection pattern CP1, the second connection pattern CP2, and/or the third connection pattern CP3. The under bump pattern UBM may be connected to the connection terminal 900 that is to be described later. The first connection pattern CP1 may be connected to the bridge die 500 that is to be described later. The second connection pattern CP2 and the third connection pattern CP3 may be connected to the passive elements 600 and 700.

The under bump pattern UBM, the first connection pattern CP1, the second connection pattern CP2, and the third connection pattern CP3 may be disposed at the lower surface RD1_BS of the first redistribution layer RD1. A lower surface of each of the under bump pattern UBM, the first connection pattern CP1, the second connection pattern CP2, and the third connection pattern CP3 might not be covered with the first redistribution insulating film IL1.

In FIG. 2, the number of under bump patterns UBM is shown as being five. However, embodiments of the present inventive concept are not limited thereto. Similarly, the number of the first connection patterns CP1, the number of the second connection patterns CP2, and the number of the third connection patterns CP3 are shown as being five, two, and two, respectively. However, this is only an example and the present inventive concept is not limited thereto.

Each of the under bump pattern UBM, the first connection pattern CP1, the second connection pattern CP2, and the third connection pattern CP3 is illustrated as having a rectangular shape. However, embodiments of the present inventive concept are not limited thereto. Each of the under bump pattern UBM, the first connection pattern CP1, the second connection pattern CP2, and the third connection pattern CP3 may have a circular plate shape, an elliptical plate shape, or a polygonal plate shape.

Each of the under bump pattern UBM, the first connection pattern CP1, the second connection pattern CP2, and the third connection pattern CP3 may include a conductive material, for example, a metal material such as aluminum (Al), copper (Cu), nickel (Ni), tungsten (W), platinum (Pt), and gold (Au). However, embodiments of the present inventive concept are not limited thereto.

The second to fourth redistribution insulating films IL2, IL3, and IL4 may be sequentially stacked on the first redistribution insulating film IL1.

A plurality of first redistribution patterns RP1 may be disposed within the second to fourth redistribution insulating films IL2, IL3, and IL4. The number and arrangement of the plurality of first redistribution patterns RP1 are not limited to those illustrated in FIG. 2.

Each of the plurality of first redistribution patterns RP1 may include a first wiring portion L1 and a first via portion V1. The first via portion V1 may be a portion for vertical (e.g., the third direction D3) connection, and the first wiring portion L1 may be a portion for horizontal (e.g., the first direction D1 or second direction D2) connection. For example, the first via portions V1 may penetrate the second to fourth redistribution insulating films IL2, IL3, and IL4 and may connect the first wiring portions L1 to each other. In embodiments of the present inventive concept, a width of the first wiring portion L1 may be greater than a width of the first via portion V1.

The first wiring portion L1 may extend in the first direction D1 and/or the second direction D2. The width of the first wiring portion L1 may be greater than the width of the first via portion V1. The first via portion V1 may be disposed under the first wiring portion L1. The first via portion V1 may protrude in the third direction D3 from the first wiring portion L1. For example, the first via portion V1 may protrude from the first wiring portion L1 toward the lower surface RD1_BS of the first redistribution layer RD1. A width of the uppermost portion of the first via portion V1 may be greater than a width of the lowermost portion of the first via portion V1. For example, the first via portion V1 may have a tapered shape.

The first redistribution patterns RP1 may be electrically connected to the under bump pattern UBM, the first connection pattern CP1, the second connection pattern CP2, and the third connection pattern CP3. The first redistribution patterns RP1 may include a metal material such as copper (Cu), aluminum (Al), tungsten (W) or titanium (Ti). However, embodiments of the present disclosure are not limited thereto.

The first semiconductor chip 100 and the second semiconductor chip 200 may be disposed on the upper surface RD1_US of the first redistribution layer RD1. The first semiconductor chip 100 and the second semiconductor chip 200 may be spaced apart from each other in the first direction D1. The first semiconductor chip 100 and the second semiconductor chip 200 may be spaced apart from each other in the first direction D1 by a first spacing R1.

Each of the first semiconductor chip 100 and the second semiconductor chip 200 may be a logic chip. For example, each of the first semiconductor chip 100 and the second semiconductor chip 200 may be an application processor (AP) such as a CPU (Central Processing Unit), a GPU (Graphics Processing Unit), an FPGA (Field-Programmable Gate Array), a digital signal processor, an encryption processor, a microprocessor, a microcontroller, an ASIC (Application-Specific IC), etc. However, embodiments of the present inventive concept are not limited thereto.

The first semiconductor chip 100 and the second semiconductor chip 200 may be electrically connected to the first redistribution layer RD1. For example, the first semiconductor chip 100 may include a plurality of first chip pads PD1. The second semiconductor chip 200 may include a plurality of second chip pads PD2. The first chip pad PD1 and the second chip pad PD2 may be used to electrically connect the first semiconductor chip 100 and the second semiconductor chip 200 with other components, respectively. A lower surface of the first chip pad PD1 and a lower surface of the second chip pad PD2 might not be covered with a lower surface of the first semiconductor chip 100 and a lower surface of the second semiconductor chip 200, respectively. For example, lower surfaces of the first chip pads PD1 may be exposed by the first semiconductor chip 100, and lower surfaces of the second chip pads PD2 may be exposed by the second semiconductor chip 200.

Each of the first chip pad PD1 and the second chip pad PD2 may include, but is not limited to, a metal material such as aluminum (Al), copper (Cu), nickel (Ni), tungsten (W), platinum (Pt), and gold (Au).

A plurality of first connection members CM1 may be disposed between the first semiconductor chip 100 and the first redistribution layer RD1. A plurality of second connection members CM2 may be disposed between the second semiconductor chip 200 and the first redistribution layer RD1.

The first chip pad PD1 and the first redistribution patterns RP1 may be connected to each other via the first connection member CM1. The second chip pad PD2 and the first redistribution patterns RP1 may be connected to each other via the second connection member CM2.

Each of the first connection member CM1 and the second connection member CM2 may be a solder bump including, for example, tin (Sn) or a tin (Sn) alloy. However, embodiments of the present inventive concept are not limited thereto. Each of the first connection member CM1 and the second connection member CM2 may have various shapes such as a land, a ball, a pin, and a pillar.

Each of the first connection member CM1 and the second connection member CM2 may be formed as a single layer or a stack of multiple layers. When each of the first connection member CM1 and the second connection member CM2 is formed as a single layer, each of the first connection member CM1 and the second connection member CM2 may include, for example, tin-silver (Sn—Ag) solder or copper (Cu). When each of the first connection member CM1 and the second connection member CM2 is formed as a stack of multilayers, each of the first connection member CM1 and the second connection member CM2 may include, for example, copper (Cu) filler and solder. However, the technical idea of the present inventive concept is not limited thereto, and the number, the spacing, the arrangement, etc. of the first connection member CM1 and the second connection member CM2 are not limited to those as illustrated, and may vary depending on a design.

Each of the first semiconductor chip 100 and the second semiconductor chip 200 may be a semiconductor chiplet die. The semiconductor chiplet die may be a unit that constitutes a semiconductor die including one or more cores. The semiconductor chiplet dies may be assembled with each other to function as a single semiconductor die. As the demand for high performance of the semiconductor product increases, the wafer is becoming larger in an area size, thereby causing problems related to a wafer yield and a manufacturing cost. According to embodiments of the present inventive concept, the semiconductor chip is produced as the chiplet, and the chiplets are packaged with each other, so that a semiconductor production yield may be increased and a semiconductor production cost may be reduced.

Although FIG. 2 illustrates that two semiconductor chips 100 and 200 are disposed on the first redistribution layer RD1, an embodiment of the present inventive concept is not limited thereto. One or three or more semiconductor chips may be mounted on the first redistribution layer RD1.

The first mold film M1 may be disposed on the upper surface RD1_US of the first redistribution layer RD1. A side surface of the first mold film M1 and a side surface of the first redistribution layer RD1 may be coplanar with each other.

The first mold film M1 may cover the first semiconductor chip 100 and the second semiconductor chip 200. For example, the first mold film M1 may cover an upper surface, a side surface, and a lower surface of each of the first semiconductor chip 100 and the second semiconductor chip 200. For example, the first mold film M1 may be disposed between the first semiconductor chip 100 and the second semiconductor chip 200. The first mold film M1 may surround the first connection member CM1 and the second connection member CM2 disposed on the first redistribution layer RD1. The first mold film M1 may cover a portion of the first redistribution patterns RP1 not covered with the fourth redistribution insulating film IL4. The first mold film M1 may cover the plurality of molding vias MV that are to be described later.

The first mold film M1 may include an insulating polymer material such as an epoxy molding compound (EMC). However, embodiments of the present inventive concept are not limited thereto. For example, the first mold film M1 may include an epoxy-based resin, benzocyclobutene, or polyimide.

The plurality of molding vias MV may be disposed between the first redistribution layer RD1 and the second redistribution layer RD2. The plurality of molding vias MV may extend through the first mold film M1. For example, the plurality of molding vias MV may extend in an elongate manner in the third direction D3.

The plurality of molding vias MV may extend through the first mold film M1 to electrically connect the first redistribution layer RD1 and the second redistribution layer RD2 to each other. For example, an upper part of the molding via MV may be in contact with a connection pad PD9 that is included in the second redistribution layer RD2, and a bottom part of the molding via MV may be in contact with the first redistribution pattern RP1 that is included in the first redistribution layer RD1.

The plurality of molding vias MV may be spaced apart from the first semiconductor chip 100 and the second semiconductor chip 200 in the first direction D1 and the second direction D2. As shown in FIG. 1, in a plan view, each of the first semiconductor chip 100 and the second semiconductor chip 200 may be surrounded with the plurality of molding vias MV.

Each of the plurality of molding vias MV may have, for example, a cylindrical post shape. However, embodiments of the present inventive concept are not limited thereto. Each of the plurality of molding vias MV may include, but is not limited to, tin (Sn), indium (In), bismuth (Bi), antimony (Sb), copper (Cu), silver (Ag), zinc (Zn), lead (Pb), or combinations thereof.

The second redistribution layer RD2 may be disposed on the first mold film M1. The second redistribution layer RD2 may be spaced apart from the first redistribution layer RD1 in the third direction D3. The second redistribution layer RD2 may cover an upper surface of the first mold film M1.

The second redistribution layer RD2 may include redistribution insulating films IL5, IL6, and IL7 and second redistribution patterns RP2.

The second redistribution layer RD2 may include the fifth redistribution insulating film IL5. For example, the fifth redistribution insulating film IL5 may include an insulating polymer or a photoimageable dielectric (PID). For example, the photoimageable polymer may include at least one of a photoimageable polyimide, polybenzoxazole (PBO), a phenol-based polymer, or a benzocyclobutene-based polymer.

The fifth redistribution insulating film IL5 may be a layer that is disposed at the lowest level among the plurality of redistribution insulating films IL5, IL6, and IL7 included in the second redistribution layer RD2.

The connection pad PD9 may be disposed within the fifth redistribution insulating film IL5. The connection pad PD9 may include a conductive material, for example, copper. The connection pads PD9 may be in contact with the molding vias MV.

The second redistribution pattern RP2 may include a plurality of second redistribution patterns. As shown in FIG. 2, each of the second redistribution patterns RP2 may include a second wiring portion L2 and a second via portion V2. The second via portion V2 of the second redistribution pattern RP2 may be disposed within the fifth redistribution insulating film IL5.

The second wiring portion L2 may extend in the first direction D1 or the second direction D2 of the second redistribution layer RD2. For example, the second via portions V2 may penetrate the fifth to seventh redistribution insulating films redistribution insulating films IL5, IL6, and IL7 and may connect the second wiring portions L2 to each other. A width of the second wiring portion L2 may be larger than a width of the second via portion V2. The second via portion V2 may be disposed under the second wiring portion L2. The second via portion V2 may protrude in the third direction D3 from the second wiring portion L2. A width of the lowermost portion of the second via portion V2 may be smaller than a width of the uppermost portion of the second via portion V2. For example, the second via portion V2 may have a tapered shape.

Each of the second redistribution patterns RP2 may include a metal material such as copper (Cu), aluminum (Al), tungsten (W), or titanium (Ti). However, embodiments of the present inventive concept are not limited thereto.

The second redistribution layer RD2 may further include the sixth redistribution insulating film IL6 and the seventh redistribution insulating film IL7. Each of the sixth and seventh redistribution insulating films IL6 and IL7 may include the second redistribution patterns RP2, just as the fifth redistribution insulating film IL5 may include.

In FIG. 2, the second redistribution layer RD2 is illustrated as including three redistribution insulating films IL5, IL6, and IL7. However, this is only an example, and the present inventive concept is not limited thereto. The second redistribution layer RD2 may include two or more redistribution insulating films including the second redistribution patterns RP2 received therein.

The bridge die 500 may be disposed on the lower surface RD1_BS of the first redistribution layer RD1. The bridge die 500 may include a first surface 500_S1 and a second surface 500_S2. The first surface 500_S1 faces the lower surface RD1_BS of the first redistribution layer RD1, and the second surface 500_S2 is opposite to the first surface 500_S1 in the third direction D3.

The bridge die 500 may overlap the first semiconductor chip 100 and the second semiconductor chip 200 in the third direction D3. A length R2 of the bridge die 500 in the first direction D1 may be greater than the spacing R1 between the first semiconductor chip 100 and the second semiconductor chip 200.

The bridge die 500 may include a substrate 501 and a connection structure IS.

The substrate 501 may include a semiconductor substrate, such as a silicon substrate, a germanium substrate, a silicon-germanium substrate, a silicon carbon substrate, etc. In addition, the substrate 501 may include a silicon-on-insulator (SOI) substrate or a germanium-on-insulator (GOI) substrate, etc.

The connection structure IS may be disposed on the substrate 501. The connection structure IS may include a dielectric layer 502 and a metal line 503. The dielectric layer 502 may include IMD (Inter-Metal Dielectric) layers. The metal line 503 may be formed within the dielectric layer 502.

The bridge die 500 may include a plurality of contact pads 504. Each of the contact pads 504 may include a metal material such as aluminum (Al), copper (Cu), nickel (Ni), tungsten (W), platinum (Pt), and gold (Au). However, embodiments of the present inventive concept are not limited thereto.

A connection member 505 may be disposed between the bridge die 500 and the first redistribution layer RD1. The connection member 505 may include a pillar portion 505B and a solder portion 505A. The pillar portion 505B may be is connected to the contact pad 504, and the solder portion 505A may connect the pillar portion 505B and the first connection pattern CP1 to each other. For example, the pillar portion 505B may contact the contact pad 504.

An underfill film 506 may be disposed on a first surface 500_1S of the bridge die 500. The underfill film 506 may be disposed on a lower surface RD1_BS of the first redistribution layer RD1. The underfill film 506 may be interposed between the bridge die 500 and the first redistribution layer RD1. The underfill film 506 may cover the connection member 505 while being disposed between the bridge die 500 and the lower surface RD1_BS of the first redistribution layer RD1.

The underfill film 506 may include, but is not limited to, an insulating polymer material such as an epoxy molding compound (EMC). For example, the underfill film 506 may include an epoxy-based resin, benzocyclobutene, or polyimide.

The bridge die 500 may connect the first semiconductor chip 100 and the second semiconductor chip 200 to each other. For example, the bridge die 500 may electrically connect the first connection member CM1, which is attached to a lower surface of the first semiconductor chip 100, and the second connection member CM2, which is attached to a lower surface of the second semiconductor chip 200, to each other. The bridge die 500 may provide an interface for signal exchange between the first semiconductor chip 100 and the second semiconductor chip 200. For example, the bridge die 500 may be a semiconductor die that serves as a UCIe (Universal Chiplet Interconnect Express) for the interface between the first semiconductor chip 100 and the second semiconductor chip 200.

Referring to FIG. 3 to FIG. 5, the bridge die 500, the second mold film M2, and the protective film PL are described in detail.

Referring to FIG. 3 to FIG. 5, the bridge die 500 may have a hexahedral shape. The bridge die 500 may include a first surface 500_S1 and a second surface 500_S2 that are opposite to each other in the third direction D3, a first side surface 500_SW1 and a second side surface 500_SW2 that are opposite to each other in the first direction D1, and a third side surface 500_SW3 and a fourth side surface 500_SW4 that are opposite to each other in the second direction D2.

A second mold film M2 may be disposed on the side surfaces 500_SW1, 500_SW2, 500_SW3, and 500_SW4 of the bridge die 500. The second mold film M2 may cover the side surfaces 500_SW1, 500_SW2, 500_SW3, and 500_SW4 of the bridge die 500. For example, the second mold film M2 may cover the first side surface 500_SW1, the second side surface 500_SW2, the third side surface 500_SW3, and the fourth side surface 500_SW4 of the bridge die 500. For example, the second mold film M2 may completely cover the first side surface 500_SW1, the second side surface 500_SW2, the third side surface 500_SW3, and the fourth side surface 500_SW4 of the bridge die 500. The second mold film M2 may cover a side surface of the substrate 501 and a side surface of the connection structure IS. For example, the second mold film M2 may surround the connection structure IS.

The second mold film M2 may include a first surface M2_S1 and a second surface M2_S2 that are opposite to each other in the third direction D3. The first surface M2_S1 may face the lower surface RD1_BS of the first redistribution layer RD1. The protective film PL may be disposed on the second surface M2_S2 of the second mold film M2. For example, the second surface M2_S2 may contact the protective film PL.

The first surface M2_S1 of the second mold film M2 may be coplanar with the first surface 500_S1 of the bridge die 500. The first surface M2_S1 of the second mold film M2 may contact the underfill film 506. In embodiments of the present inventive concept, the underfill film 506 may cover at least a portion of the first surface M2_S1 of the second mold film M2. When the underfill film 506 covers the first surface M2_S1 of the second mold film M2, the first surface M2_S1 of the second mold film M2 might not be exposed. For example, the first surface M2_S1 of the second mold film M2 may be completely covered by the underfill film 506.

The second surface M2_S2 of the second mold film M2 may be coplanar with the second surface 500_S2 of the bridge die 500. The second surface M2_S2 of the second mold film M2 may be coplanar with a lower surface of the substrate 501.

The second mold film M2 may include an insulating polymer material such as an epoxy molding compound (EMC). However, embodiments of the present inventive concept are not limited thereto. For example, the second mold film M2 may include an epoxy-based resin, benzocyclobutene, or polyimide.

The protective film PL may be disposed on the second surface 500_S2 of the bridge die 500. The protective film PL may be disposed on the second surface M2_S2 of the second mold film M2. The protective film PL may cover the second surface 500_S2 of the bridge die 500 and the second surface M2_S2 of the second mold film M2. For example, the protective film PL may be disposed on the substrate 501.

A portion of the bridge die 500 may be surrounded by the protective film PL and the second mold film M2, and the surrounded portion of the bridge die 500 might not be exposed. For example, the portion of the bridge die 500 is collectively surrounded by the protective film PL and the second mold film M2, ensuring that the portion remains unexposed. The second mold film M2 covers the side surfaces of the bridge die 500, and the protective film PL covers the second surface 500_S2 of the bridge die 500. As a result, the side surfaces and the second surface 500_S2 of the bridge die 500, which are enclosed and/or surround by both the protective film PL and the second mold film M2, might not be exposed.

The protective film PL may overlap the bridge die 500 and the second mold film M2 in the third direction D3. A side surface of the protective film PL and a side surface of the second mold film M2 may be coplanar with each other.

A third length L3 of the protective film PL, in the first direction D1, may be equal to a sum of a first length L1 of the bridge die 500, in the first direction D1, and a second length L2 of the second mold film M2, in the first direction D1.

The protective film PL may include a material that is different from a material that is included in the second mold film M2. For example, the protective film PL may include a material that is different from EMC. The protective film PL may be an adhesive tape protecting the second surface 500_S2 of the bridge die 500.

The connection terminal 900 may be disposed on the lower surface RD1_BS of the first redistribution layer RD1. The connection terminal 900 may be bonded to the under bump pattern UBM that is disposed in the first redistribution insulating film IL1. For example, the connection terminal 900 may be in contact with the under bump pattern UBM.

For example, the connection terminal 900 may include a conductive material, and may include at least one of aluminum (Al), copper (Cu), tungsten (W), platinum (Pt), gold (Au), nickel (Ni), tin (Sn), and/or silver (Ag). The semiconductor package 1000 may be connected to another external component via the connection terminal 900. For example, the semiconductor package 1000 may exchange signals with an external component via the connection terminal 900.

The first passive element 600 may be disposed on the lower surface RD1_BS of the first redistribution layer RD1. The first passive element 600 may include a contact surface facing the first redistribution layer RD1 and a non-contact surface opposite to the contact surface in the third direction D3. The contact surface of the first passive element 600 may contact the redistribution layer RD1. The first passive element 600 may include a side surface connecting the contact surface and the non-contact surface to each other. In this regard, the non-contact surface may refer to a surface positioned opposite to a surface facing the first redistribution layer RD1, and thus, the non-contact surface of the first passive element 600 is exposed to an outside out of the semiconductor package 1000. For example, the contact surface may be an upper surface of the first passive element 600, and the non-contact surface may be a lower surface of the first passive element 600.

The first passive element 600 may include, for example, a capacitor, an inductor, beads, etc. For example, the first passive element 600 may be a silicon (Si) capacitor in a chip form having a high electric capacity.

The contact surface of the first passive element 600 may include a contact terminal. The contact terminal of the first passive element 600 is a component for electrically connecting the first passive element 600 to the component of the first redistribution layer RD1, and may include a conductive material.

A plurality of connection members 601 may be disposed between the first passive element 600 and the first redistribution layer RD1. A bottom part of the connection member 601 may be in contact with the contact terminal disposed at the contact surface of the first passive element 600, while an upper part of the connection member 601 may be in contact with the second connection pattern CP2 disposed in the first redistribution insulating film IL1. The connection member 601 may be electrically connected to the contact terminal of the first passive element 600 and the second connection pattern CP2.

The underfill film 602 may be disposed between the first passive element 600 and the first redistribution layer RD1. The underfill film 602 may be disposed to be spaced apart from the bridge die 500, the second passive element 700, and the connection terminal 900. The underfill film 602 may electrically insulate the first passive element 600 from the bridge die 500, the second passive element 700, and the connection terminal 900. The underfill film 602 may cover an entirety of the contact surface of the first passive element 600, a portion of the lower surface RD1_BS of the first redistribution layer RD1, and the connection member 601. The underfill film 602 may include an insulating resin and, for example, EMC.

The second passive element 700 may be disposed on the lower surface RD1_BS of the first redistribution layer RD1. The second passive element 700 may be, for example, a capacitor. For example, the second passive element 700 may be a silicon capacitor, a multilayer ceramic capacitor (MLCC), or a low inductance ceramic capacitor (LICC). However, the present inventive concept is not limited thereto.

Each of a first conductive pad 701 and a second conductive pad 702 may be disposed on the lower surface RD1_BS of the first redistribution layer RD1. The first conductive pad 701 and the second conductive pad 702 may be disposed spaced apart from each other. The first conductive pad 701 and the second conductive pad 702 may protrude in the third direction D3 from the lower surface RD1_BS of the first redistribution layer RD1. Each of the first conductive pad 701 and the second conductive pad 702 may include a conductive material.

The first conductive pad 701 and the second conductive pad 702 may be electrically connected to the third connection pattern CP3 that is disposed within the first redistribution insulating film IL1. The first conductive pad 701 and the second conductive pad 702 may be electrically connected to the second passive element 700. For example, the second passive element 700 may be disposed between the first and second conductive pads 701 and 702. The first conductive pad 701 and the second conductive pad 702 may electrically connect the first redistribution layer RD1 and the second passive element 700 to each other.

Each of the first conductive pad 701 and the second conductive pad 702 may ground the second passive element 700. In addition, each of the first conductive pad 701 and the second conductive pad 702 may supply power to the second passive element 700.

The second sub-semiconductor package SP2 may be disposed on the second redistribution layer RD2. The second sub-semiconductor package SP2 may include a first package substrate SUB1, a third semiconductor chip 300, a first bonding wire W1, a third mold film M3, and a connection member CM3.

The first package substrate SUB1 may include an upper surface and a lower surface that are opposite to each other in the third direction D3. The first package substrate SUB1 may be a printed circuit board (PCB). When the first package substrate SUB1 is embodied as the printed circuit board, the first package substrate SUB1 may be a multilayer circuit board having vias and various circuits therein.

The first package substrate 501 may include a first substrate upper pad PD4 and a first substrate lower pad PD3. The first substrate upper pad PD4 may be adjacent to an upper surface of the first package substrate SUB1. The first substrate lower pad PD3 may be adjacent to a lower surface of the first package substrate SUB1.

The third semiconductor chip 300 may be disposed on the first package substrate SUB1. An adhesive layer 300T may attach the third semiconductor chip 300 to the first package substrate SUB1. The adhesive layer 300T may be disposed between the first package substrate SUB1 and the third semiconductor chip 300. The adhesive layer 300T may be a DAF (Die Attach Film) including epoxy.

The third semiconductor chip 300 may be a memory chip. For example, the third semiconductor chip 300 may be a volatile memory such as a DRAM (dynamic random access memory) or an SRAM (static random access memory), or a non-volatile memory such as a flash memory, a PRAM (phase-change random access memory), an MRAM (magnetoresistive random access memory), a FeRAM (ferroelectric random access memory), or an RRAM (resistive random access memory).

The third semiconductor chip 300 may be connected to the first package substrate SUB1 via a chip pad PD5 disposed on an upper surface thereof. For example, the third semiconductor chip 300 and the first package substrate SUB1 may be electrically connected to each other via the first bonding wire W1 connecting the chip pad PD5 and the first substrate upper pad PD4 to each other.

The connection member CM3 may be disposed between the second redistribution layer RD2 and the first package substrate SUB1. For example, an upper part of the connection member CM3 may be in contact with the first substrate lower pad PD3, and a bottom part of the connection member CM3 may be in contact with the second redistribution pattern RP2 of the second redistribution layer RD2. The connection member CM3 may electrically connect the first package substrate SUB1 and the second redistribution layer RD2 to each other. The connection member CM4 may include a conductive material.

The third mold film M3 may be disposed on the first package substrate SUB1. The third mold film M3 may cover an upper surface of the first package substrate SUB1, the upper surface and a side surface of the third semiconductor chip 300, and the first bonding wire W1. The third mold film M3 may include an insulating polymer such as EMC.

The third sub-semiconductor package SP3 may be disposed on the second redistribution layer RD2. The third sub-semiconductor package SP3 may be disposed to be spaced apart from the second sub-semiconductor package SP2 in the first direction D1.

The third sub-semiconductor package SP3 may include a second package substrate SUB2, a fourth semiconductor chip 400, a second bonding wire W2, a fourth mold film M4, and a connection member CM4.

The second package substrate SUB2 may include an upper surface and a lower surface opposite to each other in the third direction D3. The second package substrate SUB2 may be a printed circuit board (PCB).

The second package substrate SUB2 may include a second substrate upper pad PD7 and a second substrate lower pad PD6. The second substrate upper pad PD7 may be adjacent to the upper surface of the second package substrate SUB2. The second substrate lower pad PD6 may be adjacent to the lower surface of the second package substrate SUB2.

The fourth semiconductor chip 400 may be disposed on the second package substrate SUB2. An adhesive layer 400T may attach the fourth semiconductor chip 400 to the second package substrate SUB2. The adhesive layer 400T may be disposed between the second package substrate SUB1 and the fourth semiconductor chip 400. The adhesive layer 400T may be a DAF (Die Attach Film) including epoxy.

The fourth semiconductor chip 400 may be a memory chip. For example, the fourth semiconductor chip 400 may be a volatile memory such as a DRAM (dynamic random access memory) or an SRAM (static random access memory), or a non-volatile memory such as a flash memory, a PRAM (phase-change random access memory), an MRAM (magnetoresistive random access memory), a FeRAM (ferroelectric random access memory), or an RRAM (resistive random access memory).

The fourth semiconductor chip 400 may be connected to the second package substrate SUB2 via a chip pad PD8 disposed on an upper surface thereof. For example, the fourth semiconductor chip 400 and the second package substrate SUB2 may be electrically connected to each other via the second bonding wire W2 connecting the chip pad PD8 and the second substrate upper pad PD7 to each other.

The connection member CM4 may be disposed between the second redistribution layer RD2 and the second package substrate SUB2. For example, an upper part of the connection member CM4 may be in contact with the second substrate lower pad PD6, and a bottom part of the connection member CM4 may be in contact with the second redistribution pattern RP2 of the second redistribution layer RD2. The connection member CM4 may electrically connect the second package substrate SUB2 and the second redistribution layer RD2 to each other. The connection member CM4 may include a conductive material.

The fourth mold film M4 may be disposed on the second package substrate SUB2. The fourth mold film M4 may cover the upper surface of the second package substrate SUB2, the upper surface and a side surface of the fourth semiconductor chip 400, and the second bonding wire W2. The fourth mold film M4 may include an insulating polymer such as EMC.

Although FIG. 2 illustrates that each of the second and third sub-semiconductor packages SP2 and SP3 includes only one semiconductor chip, the present inventive concept is not limited thereto. In some embodiments of the present inventive concept, each of the second and third sub-semiconductor packages SP2 and SP3 may include a structure in which a plurality of semiconductor chips are vertically stacked.

Furthermore, although FIG. 2 illustrates that each of the second and third sub-semiconductor packages SP2 and SP3 includes the wire bonding structure, an embodiment of the present inventive concept is not limited thereto. For example, the second or third sub-semiconductor package SP2 or SP3 may include a structure in which a plurality of vertically stacked memory dies are connected to each other via a TSV (Through Silicon Via) structure.

The HPB 800 may be disposed on the second redistribution layer RD2. The HPB 800 may be disposed in an area where the second redistribution pattern RP2 is not formed in the second redistribution layer RD2. The HPB 800 may be attached to the second redistribution layer RD2 via a tape 800T. The HPB 800 may function to dissipate heat that is generated by the first semiconductor chip 100 and the second semiconductor chip 200 to an exterior of the semiconductor package 1000.

In this way, the semiconductor package 1000 may have a POP (Package On Package) structure in which each of the second sub-semiconductor package SP2 including the memory chip such as a DRAM, and the third sub-semiconductor package SP3 including the memory chip such as a DRAM is disposed on top of the first sub-semiconductor package SP1 including the logic chip such as an application processor chip. In FIG. 2, it is illustrated that two semiconductor packages, that is, the second and third sub-semiconductor packages SP2 and SP3 are disposed on the first sub-semiconductor package SP1. However, an embodiment of the present inventive concept is not limited thereto. Only one sub-semiconductor package may be stacked on top of the first sub-semiconductor package SP1, and three or more sub-semiconductor packages may be stacked on top thereof.

When the bridge die 500 disposed on the lower surface RD1_BS of the first redistribution layer RD1 is exposed, there may be a risk of cracking.

However, in the semiconductor package according to embodiments of the present inventive concept, the side surface of the bridge die 500 may be covered with the second mold film M2, and the second surface 500_S2 of the bridge die 500 may be covered with the protective film PL. For example, the first side surface 500_SW1, the second side surface 500_SW2, the third side surface 500_SW3, and the fourth side surface 500_SW4 of the bridge die 500 may be covered with the second mold film M2. The second surface 500_S2 of the bridge die 500 may be covered with the protective film PL. Since the bridge die 500 is surrounded by both the second mold film M2 and the protective film PL, the bridge die 500 may be protected from an external impact. Therefore, the risk of cracking in the bridge die may be reduced.

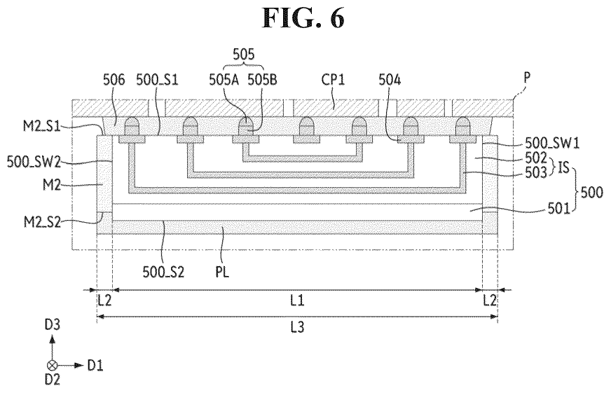

FIG. 6 is a diagram illustrating a semiconductor package according to embodiments of the present inventive concept. FIG. 6 is an enlarged drawing of a P portion of FIG. 2. For the convenience of description, descriptions that duplicate the content already provided with reference to FIGS. 1 to 5 are briefly described or omitted.

Referring to FIG. 6, side surfaces of the bridge die 500 may be covered by the second mold film M2 and the protective film PL. For example, side surfaces of the bridge die 500 may be surround by both the second mold film M2 and the protective film PL. For example, the bridge die 500 may be enclosed by the second mold film M2 and the protective film PL. The second surface 500_S2 of the bridge die 500 may be covered with the protective film PL.

The second mold film M2 may cover a portion of each of the first side surface 500_SW1 and the second side surface 500_SW2 of the bridge die 500. The second mold film M2 may cover a portion of each of the third side surface (500_SW3 in FIG. 4) and the fourth side surface (500_SW4 in FIG. 4) of the bridge die 500. There may be a step between the second surface M2_S2 of the second mold film M2 and the second surface 500_S2 of the bridge die 500. For example, a vertical level of the second surface M2_S2 of the second mold film M2 may be different from a vertical level of the second surface 500_S2 of the bridge die 500 with respect to the lower surface RD1_BS of the first redistribution layer RD1. With respect to the lower surface RD1_BS of the first redistribution layer RD1, the vertical level of the second surface M2_S2 of the second mold film M2 may be higher than the vertical level of the second surface 500_S2 of the bridge die 500. In other words, a vertical length of the second mold film M2 extending from the lower surface RD1_BS of the first redistribution layer RD1 to the second surface M2_S2 of the second mold film M2 may be smaller than a vertical length of the bridge die 50 extending from the lower surface RD1_BS of the first redistribution layer RD1 to the second surface 500_S2 of the bridge die 500.

The protective film PL may cover a portion of each of the first side surface 500_SW1 and the second side surface 500_SW2 of the bridge die 500. For example, the protective film PL may cover a portion of each of the first side surface 500_SW1 and the second side surface 500_SW2 of the bridge die 500 that is not covered by the second mold film M2. The protective film PL may cover a portion of each of the third side surface 500_SW3 and the fourth side surface 500_SW4 of the bridge die 500. For example, the protective film PL may cover a portion of each of the third side surface 500_SW3 and the fourth side surface 500_SW4 of the bridge die 500 that is not covered by the second mold film M2. The protective film PL may cover the second surface 500_S2 of the bridge die 500.

The protective film PL may include a horizontal portion and a vertical portion. The horizontal portion may extend in a horizontal direction to cover the second surface of the bridge die 500. The vertical portion may protrude from the horizontal portion in the third direction D3 to cover a portion of the side surface of the bridge die 500.

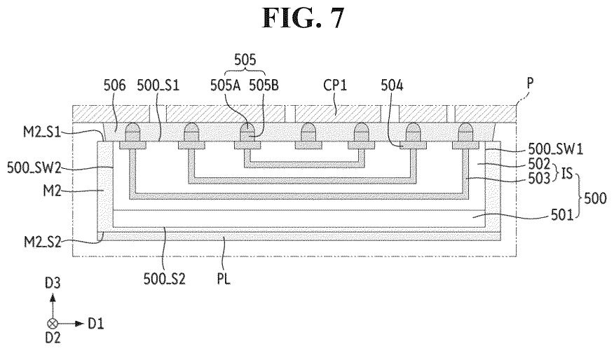

FIG. 7 is a diagram illustrating a semiconductor package according to embodiments of the present inventive concept. FIG. 7 is an enlarged drawing of the P portion of FIG. 2. For convenience of description, descriptions that duplicate the content already provided with reference to FIGS. 1 to 5 are briefly described or omitted.

Referring to FIG. 7, the second mold film M2 may cover the side surfaces and the second surface 500_S2 of the bridge die 500. For example, the second mold film M2 may cover the first side surface 500_SW1, the second side surface 500_SW2, the third side surface 500_SW3 in FIG. 4, the fourth side surface 500_SW4 in FIG. 4, and the second surface 500_S2 of the bridge die 500. The second mold film M2 may cover the second surface 500_S2 of the bridge die 500.

The protective film PL may be disposed on the second mold film M2. The protective film PL may be disposed on the second surface M2_S2 of the second mold film M2. A length of the protective film PL in the first direction D1 may be equal to a length of the second surface M2_S2 of the second mold film M2 in the first direction D1.

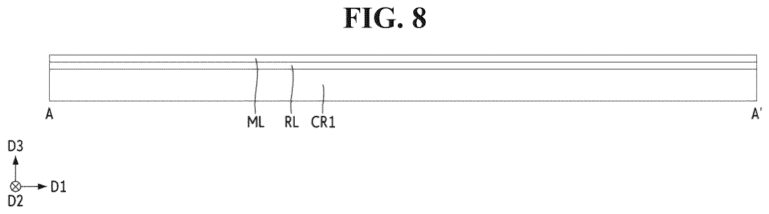

FIG. 8 to FIG. 18 are diagrams illustrating a method for manufacturing a semiconductor package according to embodiments of the present inventive concept. FIG. 8 to FIG. 18 are diagrams of intermediate structures corresponding to intermediate steps of a method for manufacturing a semiconductor package according to embodiments of the present inventive concept. For convenience of description, descriptions that duplicate descriptions that with reference to FIGS. 1 to 5 are briefly described or are omitted.

Referring to FIG. 8, a first carrier substrate CR1 may be provided.

For example, the first carrier substrate CR1 may include, but is not limited to, silicon, metal, glass, plastic, ceramic, etc. The first carrier substrate CR1 may be used for the purpose of supporting materials in forming the first sub-semiconductor package (SP1 in FIG. 2), and may be removed later if necessary.

A release layer RL may be conformally formed on the first carrier substrate CR1. The release layer RL may be in contact with the first carrier substrate CR1.

The release layer RL may include, for example, a photosensitive insulating material. The release layer RL may include, for example, epoxy or polyimide. However, the technical idea of the present disclosure is not limited thereto. That is, in embodiments of the present inventive concept, the release layer RL may be an inorganic release layer to introduce stable detachable ability. In this case, the release layer RL may be, for example, a carbon material. However, the technical idea of the present inventive concept is not limited thereto.

Next, a metal layer ML may be conformally formed on the release layer RL. For example, the metal layer ML may be in contact with the release layer RL. The metal layer ML may be selectively removed from the first carrier substrate CR1 and the release layer RL in a subsequent process. For example, the metal layer ML may include, but is not limited to, a metal such as titanium (Ti).

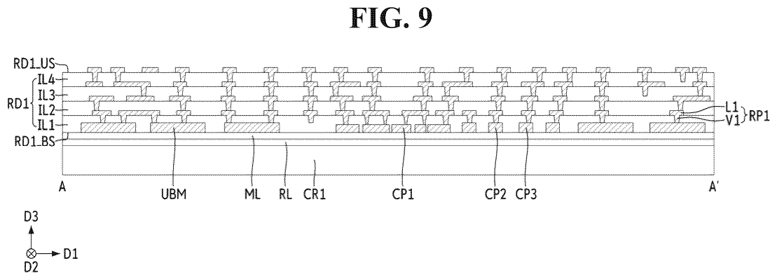

Referring to FIG. 9, the first redistribution layer RD1 may be formed on the first carrier substrate CR1.

The first redistribution layer RD1 may be formed on the first carrier substrate CR1 such that the lower surface RD1_BS of the first redistribution layer RD1 faces the first carrier substrate CR1 on which the release layer RL and the metal layer ML have been formed, and the upper surface RD1_US of the first redistribution layer RD1 is opposite to the first carrier substrate CR1.

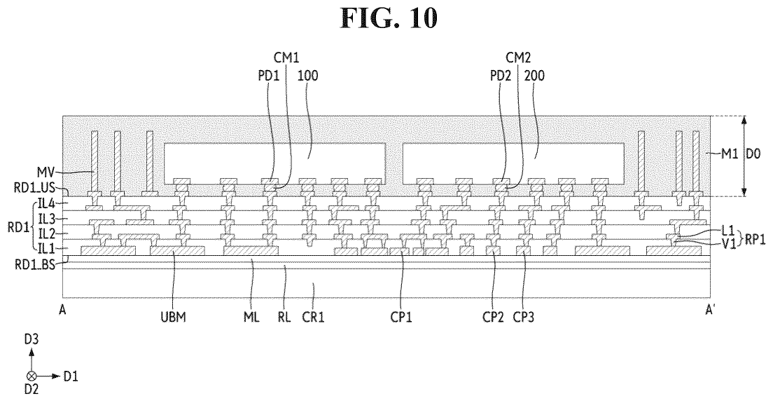

Referring to FIG. 10, the plurality of molding vias MV, the first semiconductor chip 100, and the second semiconductor chip 200 may be disposed on the first redistribution layer RD1.

The molding vias MV may be mounted on the first redistribution layer RD1 via a first wiring portion L1 on the upper surface RD1_US of the first redistribution layer RD1. The first semiconductor chip 100 may be mounted on the first redistribution layer RD1 via the first chip pad PD1 and the connection members CM1. The second semiconductor chip 200 may be mounted on the second redistribution layer RD2 via the second chip pad PD2 and the second connection member CM2.

Next, the first mold film M1 covering the plurality of molding vias MV, the first semiconductor chip 100, and the second semiconductor chip 200 may be formed on the first redistribution layer RD1. The first mold film M1 may entirely cover the first redistribution layer RD1, the first semiconductor chip 100, the second semiconductor chip 200, the molding vias MV, and the connection members CM1 and CM2.

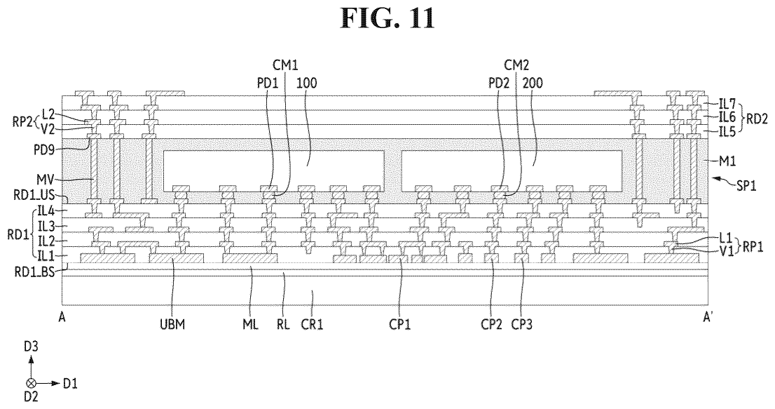

Referring to FIG. 11, a grinding process may be performed on the first mold film M1 so that a portion of the first mold film M1 may be removed.

For example, a length (D0 in FIG. 10) of the first mold film M1 in the third direction D3 before the grinding may be greater than a length D0′ of the first mold film M1 in the third direction D3 after the grinding.

At least a portion of the upper portion of the first mold film M1 may be removed in the grinding process, so that the upper surfaces of the molding vias MV may be exposed. However, an upper portion of the first mold film M1 covering the upper surface of each of the first and second semiconductor chips 100 and 200 might not be entirely removed in the grinding process. Accordingly, the upper surface of each of the first and second semiconductor chips 100 and 200 might not be exposed. However, an embodiment of the present inventive concept is not limited thereto. In embodiments of the present inventive concept, a portion of the first mold film M1 may be removed in the grinding process so that the upper surface of each of the first and second semiconductor chips 100 and 200 may be exposed. However, in the present disclosure, it is assumed that the grinding process is performed to remove at least a portion of the upper portion of the first mold film M1 such that the upper surfaces of the molding vias MV are exposed and the upper surfaces of the first and second semiconductor chips 100 and 200 are not exposed. Therefore, the upper surface of each of the plurality of molding vias MV and the upper surface of the first mold film M1 may be coplanar with each other.

Next, the second redistribution layer RD2 may be formed on the first mold film M1. The second redistribution layer RD2 may have a structure in which the fifth redistribution insulating film IL5, the sixth redistribution insulating film IL6, and the seventh redistribution insulating film IL7 are sequentially stacked. However, the number of redistribution insulating films is only an example and the present inventive concept is not limited thereto.

The fifth redistribution insulating film IL5 may include the connection pad PD9. The fifth redistribution insulating film IL5, the sixth redistribution insulating film IL6, and the seventh redistribution insulating film IL7 may include the second redistribution patterns RP2. The connection pad PD9 may be connected to the plurality of molding vias MV, so that the first redistribution layer RD1 and the second redistribution layer RD2 may be connected to each other.

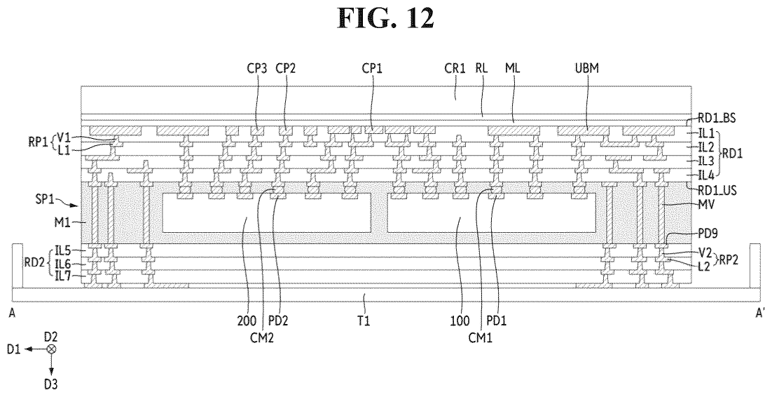

Referring to FIG. 12, a resulting structure of FIG. 11 may be turned upside down and attached to a heat-resistant tape T1.

For example, the second redistribution layer RD2 may be attached to the heat-resistant tape T1. The heat-resistant tape T1 may include a heat-resistant material to prevent the components and materials of the semiconductor package attached to the heat-resistant tape T1 from lifting off during a process of receiving thermal history, such as a reflow process, in a later process.

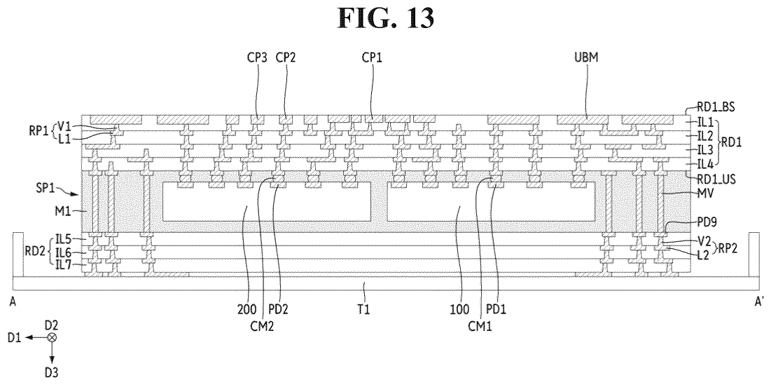

Referring to FIG. 13, the first carrier substrate CR1, the release layer RL, and the metal layer ML may be removed.

For example, the release layer RL on the first carrier substrate CR1 may be removed in a descum process, and the metal layer ML may be removed in an etching process. However, an embodiment of the present inventive concept is not limited thereto, and the first carrier substrate CR1 and the release layer RL may be removed in a laser debonding process.

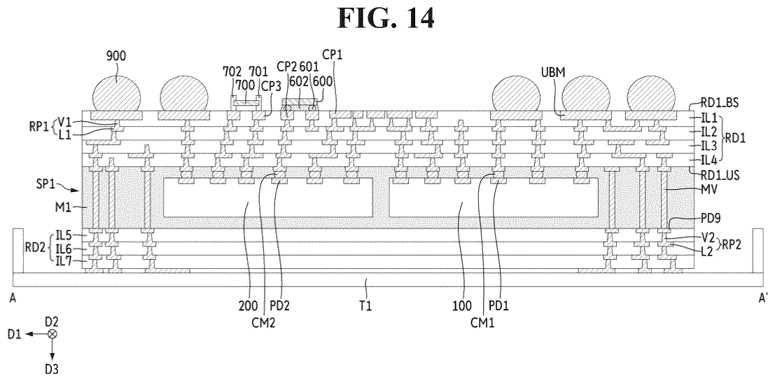

Referring to FIG. 14, the connection terminal 900, the first passive element 600, and the second passive element 700 may be formed on the lower surface RD1_BS of the first redistribution layer RD1.

For example, the connection terminals 900 may be attached to an exposed surface of the under bump pattern UBM that is not covered with the first redistribution insulating film IL1. The connection members 601 may be attached to an exposed surface of the second connection pattern CP2 not covered with the first redistribution insulating film IL1. The first and second conductive pads 701 and 702 may be attached to an exposed surface of the third connection pattern CP3 not covered with the first redistribution insulating film IL1. The first passive element 600 may be connected to the connection members 601. The first and second conductive pads 701 and 702 may be connected to the second passive element 700.

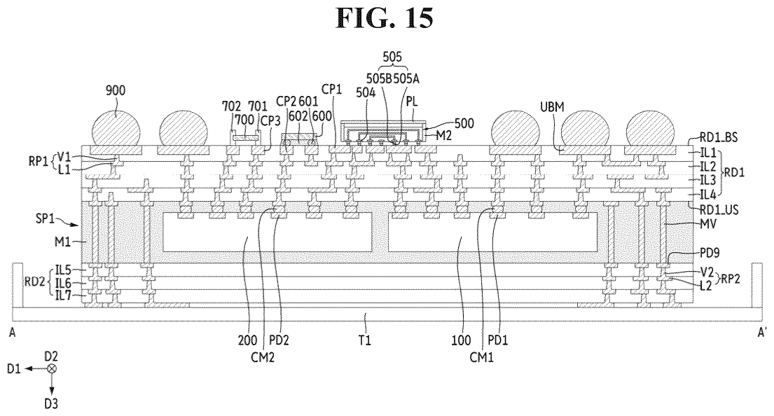

Referring to FIG. 15, while the bridge die 500 is surrounded with the second mold film M2 and the protective film PL, the bridge die may be bonded to the first redistribution layer RD1.

The bridge die 500 and the connection members 505 may be bonded to the first redistribution layer RD1 in a reflow process. For example, the bridge die 500 may be attached to the lower surface RD1_BS of the first redistribution layer RD1 so that the connection members 505 disposed on the bridge die 500 come into contact with the first connection patterns CP1 within the first redistribution insulating film IL1. Then, heat may be applied to the components between the bridge die 500 and the first redistribution layer RD1 to bond the bridge die 500 and the first redistribution layer RD1 to each other.

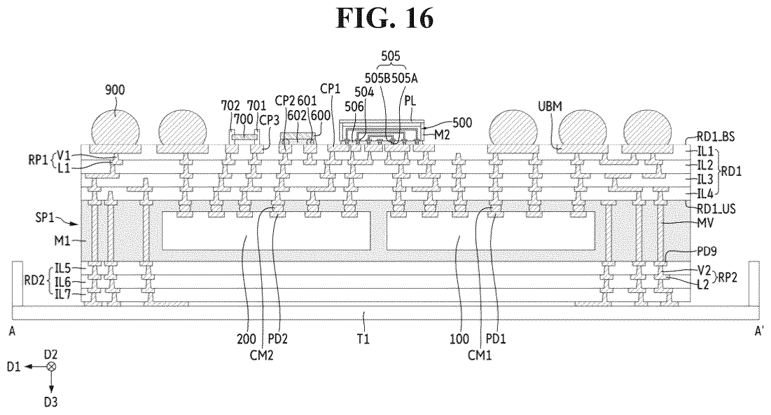

Referring to FIG. 16, the underfill film 506 may be formed between the bridge die 500 and the first redistribution layer RD1.

The underfill film 506 may cover the connection members 505 while being disposed between the bridge die 500 and the first redistribution layer RD1. After the underfill film 506 is filled into between the bridge die 500 and the first redistribution layer RD1, the underfill film may be cured to fix the bridge die 500 onto the first redistribution layer RD1.

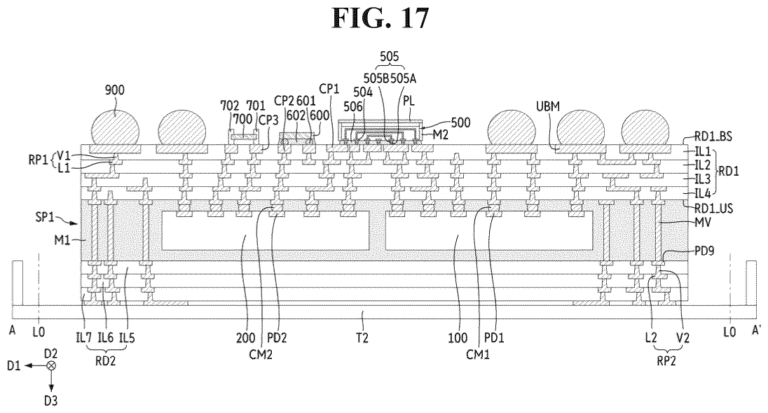

Referring to FIG. 17, the heat-resistant tape T1 may be changed to a dicing tape T2. In embodiments of the present inventive concept, the dicing tape T2 is a tape for fixing the components and materials of the semiconductor package attached to the dicing tape T2 during a subsequent sawing process. Unlike the heat-resistant tape T1, the dicing tape T2 might not include a heat-resistant material. Subsequently, the sawing process may be performed to separate the semiconductor chips from each other to form a plurality of first sub-semiconductor packages SP1.

For example, the sawing process may be performed along lines L0 to separate semiconductor chips from each other. Accordingly, the first sub-semiconductor package SP1 including the first redistribution layer RD1, the second redistribution layer RD2, the first and second semiconductor chips 100 and 200, the plurality of molding vias MV, the first mold film M1, the first passive element 600, the second passive element 700, the bridge die 500, and the connection terminals 900 may be finally manufactured.

Although only one first sub-semiconductor package SP1 is illustrated in FIG. 17, a structure in which a plurality of first sub-semiconductor packages SP1, each having the same configuration as that of the first sub-semiconductor package SP1 illustrated in FIG. 17, are attached to the dicing tape T2 may be provided in an actual process. The plurality of first sub-semiconductor packages SP1 may be separated from each other in the sawing process along the lines L0.

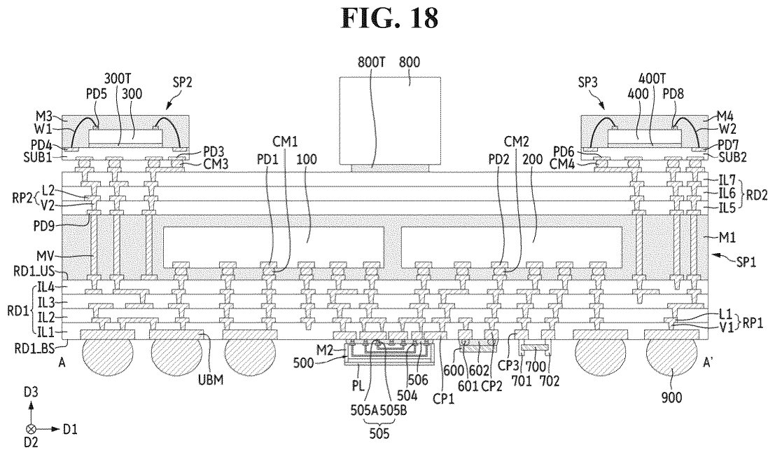

Referring to FIG. 18, the second sub-semiconductor package SP2, the third sub-semiconductor package SP3, and the HPB 800 may be mounted on the first sub-semiconductor package SP1.

Each of the second sub-semiconductor package SP2 and the third sub-semiconductor package SP3 may be stacked on top of the first sub-semiconductor package SP1 so that the first wiring portion L1 of the second redistribution layer RD2 and each of the connection members CM3 and the connection members CM4 are electrically connected to each other. The HPB 800 may be formed on an area of a surface of the second redistribution layer where the second wiring portion L2 is not formed.

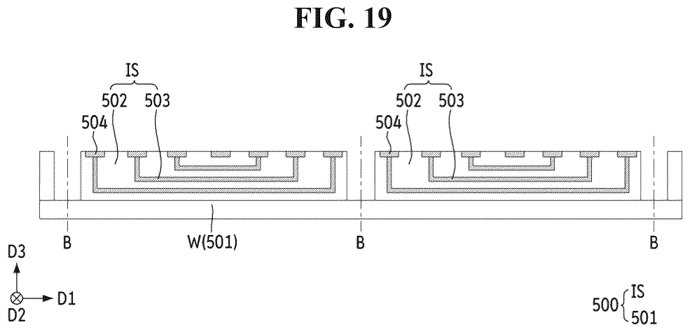

FIG. 19 to FIG. 26 are diagrams illustrating a method for manufacturing a semiconductor package according to embodiments of the present inventive concept. FIG. 19 to FIG. 26 illustrate a method for manufacturing the bridge die covered with the second mold film and the protective film PL. For convenience of description, descriptions that duplicate the content already provided with reference to FIG. 1 to FIG. 18 are briefly described or omitted.

Referring to FIG. 19, after adjusting a thickness of the bridge die 500, the sawing process may be performed to separate a plurality of bridge dies 500, which are formed on the wafer W, from each other.

For example, a dielectric layer 502 in which a metal line 503 and contact pads 504 are disposed, may be formed on the wafer W. When the bridge die 500 is manufactured, the wafer W may become a substrate 501 of the bridge die 500. Before sawing along a line B, a thickness (length in the third direction D3) of the wafer W may be adjusted. Thereafter, the plurality of bridge dies 500 may be separated from each other via the sawing operation along the line B. The bridge die 500 may include the substrate 501 and a connection structure IS. The connection structure IS may include the dielectric layer 502 and the metal line 503.

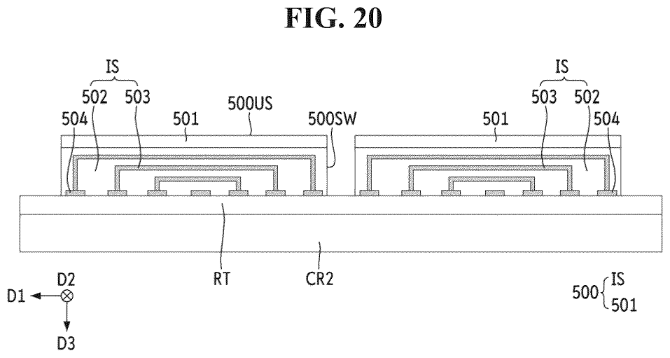

Referring to FIG. 20, a second carrier substrate CR2, to which a reconstruction tape RT is attached, may be provided. The bridge die 500 may be disposed on the second carrier substrate CR2.

The second carrier substrate CR2 may include, for example, silicon, metal, glass, plastic, ceramic, etc. However, embodiments of the present inventive concept are not limited thereto. The second carrier substrate CR2 may be used for the purpose of supporting materials in forming the bridge die 500 and may be removed later if necessary.

The reconstruction tape RT may be conformally formed on the second carrier substrate CR2. The reconstruction tape RT may be in contact with the second carrier substrate CR2.

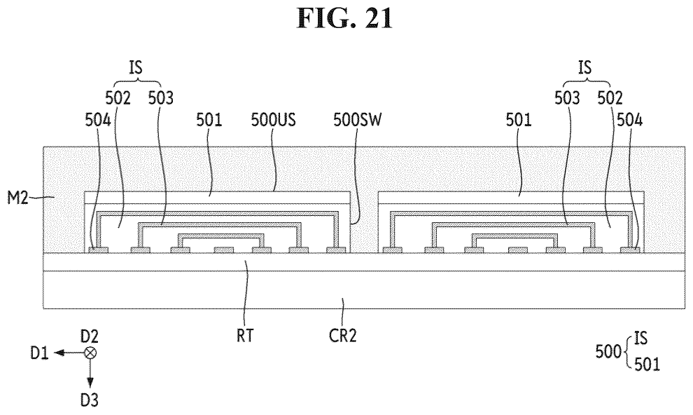

Referring to FIG. 21, the second mold film M2 may be formed on the second carrier substrate CR2. The second mold film M2 may cover the plurality of bridge dies 500. For example, the second mold film M2 may cover a side surface 500SW and an upper surface 500US of the bridge die 500. For example, the side surface 500SW may be formed from the separation of the plurality of bridge dies 500.

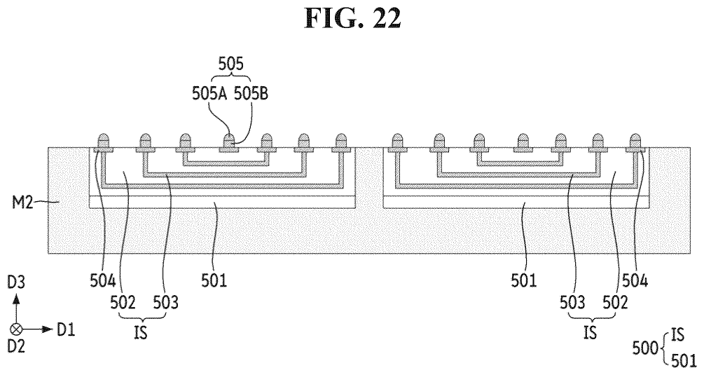

Referring to FIG. 22, a resulting structure of FIG. 21 may be flipped over, and the reconstruction tape RT and the second carrier substrate CR2 may be removed. Next, a plurality of connection members 505, each including a solder portion 505A and a pillar portion 505B, may be formed on the bridge die 500.

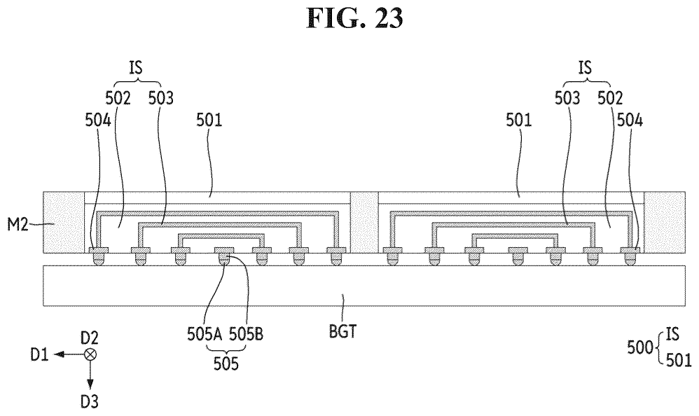

Referring to FIG. 23, a resulting structure of FIG. 22 is turned upside down and attached to a back grinding tape BGT. Subsequently, a back grinding process is performed to remove a portion of the second mold film M2.

The resulting structure of FIG. 22 may be turned upside down so that the connecting members 505 come into contact with the back grinding tape BGT. Subsequently, a portion of the second mold film M2 may be removed by using the back grinding process. The portion of the second mold film M2 may be removed to expose the upper surface of the bridge die 500. For example, an upper surface of the second mold film M2 may be coplanar with the upper surface of the bridge die 500.

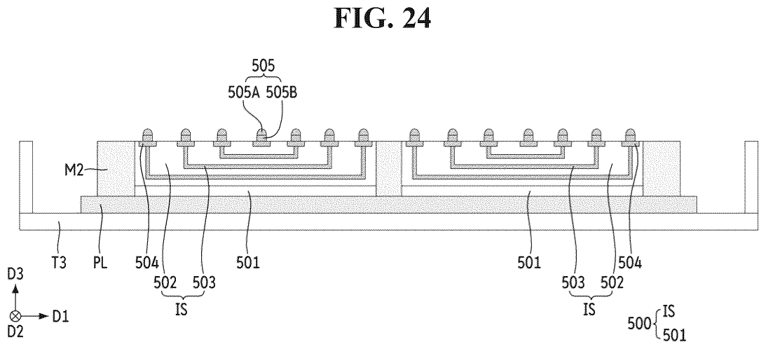

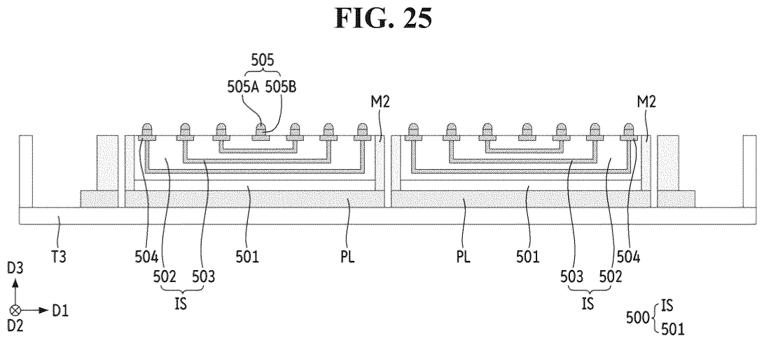

Referring to FIG. 24 and FIG. 25, a dicing tape T3 and the protective film PL disposed on the dicing tape T3 may be provided. A resulting structure of FIG. 23 is turned upside down and a surface of the bridge die 500 is attached to the protective film PL. For example, the exposed upper surface of the bridge die 500 may be attached to the protective film PL. A horizontal length of the protective film PL may be larger than a horizontal length of the resulting structure of FIG. 23.

Subsequently, the plurality of bridge dies 500 may be separated from each other using a sawing process. Each of the separated bridge dies 500 may be the bridge die 500 illustrated in FIG. 2. The side surfaces of the bridge dies 500 may be surrounded with the second mold film M2, and one surface in the third direction D3 thereof may be covered with the protective film PL. For example, the side surface of the bridge dies 500 may be completely covered by the second mold film M2.

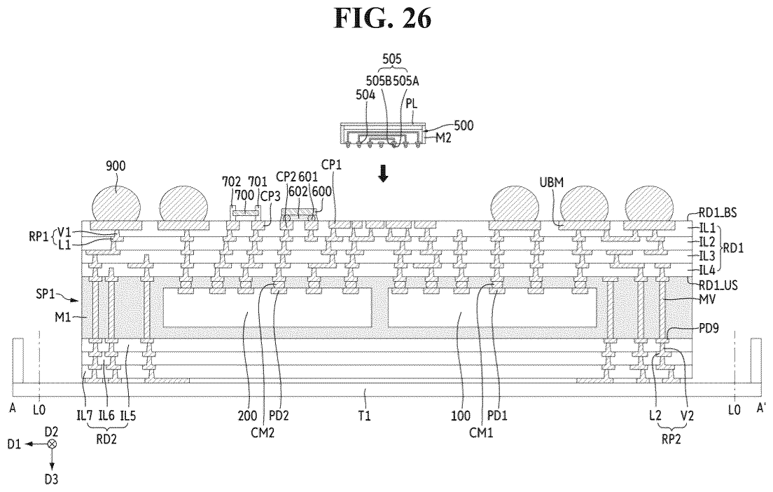

Referring to FIG. 26, the bridge die 500 may be bonded onto the lower surface RD1_BS of the first redistribution layer RD1. Thereafter, a subsequent process as described with reference to FIGS. 16 to 18 may be performed. Finally, the semiconductor package according to embodiments of the present inventive concept such as the POP structured semiconductor package 1000 as illustrated in FIG. 2 may be manufactured.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor package comprising:
a redistribution layer including an upper surface and a lower surface opposite to each other in a first direction;
a semiconductor chip disposed on the upper surface of the redistribution layer;
a bridge die disposed on the lower surface of the redistribution layer, and electrically connected to the semiconductor chip, wherein the bridge die includes a first surface and a second surface, wherein the first surface faces the semiconductor chip, and the second surface is opposite to the first surface in the first direction;
a mold film disposed on a third surface of the bridge die; and
a protective film disposed on the second surface of the bridge die.

2. The semiconductor package of claim 1, wherein the mold film includes a first surface and a second surface, wherein the first surface of the mold film faces the lower surface of the redistribution layer, and the second surface of the mold film is opposite to the first surface of the mold film in the first direction,
wherein the protective film covers the second surface of the bridge die and the second surface of the mold film.

3. The semiconductor package of claim 2, wherein the second surface of the bridge die and the second surface of the mold film are coplanar with each other.

4. The semiconductor package of claim 2, wherein with respect to the lower surface of the redistribution layer, a vertical level of the second surface of the bridge die is lower than a vertical level of the second surface of the mold film.

5. The semiconductor package of claim 1, wherein the semiconductor chip includes a first semiconductor chip and a second semiconductor chip spaced apart from the first semiconductor chip in a second direction,
wherein the bridge die overlaps each of the first semiconductor chip and the second semiconductor chip in the first direction.

6. The semiconductor package of claim 5, wherein a spacing in the second direction between the first semiconductor chip and the second semiconductor chip is smaller than a length in the second direction of the bridge die.

7. The semiconductor package of claim 1, wherein the bridge die includes a first side surface, a second side surface, a third side surface, and a fourth side surface, wherein the first side surface and the second side surface are opposite to each other in the second direction, and the third side surface and the fourth side surface are opposite to each other in a third direction,
wherein the mold film covers the first side surface, the second side surface, the third side surface, and the fourth side surface of the bridge die,
wherein the protective film covers the second surface of the bridge die.

8. The semiconductor package of claim 1, wherein the protective film overlaps the mold film and the bridge die in the first direction.

9. The semiconductor package of claim 1, wherein a length in the second direction of the protective film is equal to a sum of a length in the second direction of the mold film and a length in the second direction of the bridge die.

10. The semiconductor package of claim 1, wherein the semiconductor chip is a first semiconductor chip,
wherein the semiconductor package further comprises:
a chip mold film disposed on the upper surface of the redistribution layer and covering the semiconductor chip;
a plurality of molding vias spaced apart from the semiconductor chip and extending through the chip mold film; and
a second semiconductor chip disposed on the chip mold film.

11. The semiconductor package of claim 10, wherein the first semiconductor chip is a logic chip, and the second semiconductor chip is a memory chip.

12. A semiconductor package comprising:
a first redistribution layer including an upper surface and a lower surface opposite to each other in a first direction;
a first semiconductor chip disposed on the upper surface of the first redistribution layer;
a second semiconductor chip disposed on the upper surface of the first redistribution layer and spaced apart from the first semiconductor chip in a second direction;
a first mold film disposed on the upper surface of the first redistribution layer and covering the first semiconductor chip and the second semiconductor chip;
a second redistribution layer disposed on the first mold film;
a third semiconductor chip disposed on the second redistribution layer;
a bridge die disposed on the lower surface of the first redistribution layer and connected to the first and second semiconductor chips, wherein the bridge die includes a first surface and a second surface, wherein the first surface faces the lower surface of the first redistribution layer, and the second surface is opposite the first surface of the bridge die in the first direction;
a second mold film covering a side surface of the bridge die, wherein the second mold film includes a first surface and a second surface, wherein the first surface of the second mold film faces the lower surface of the redistribution layer, and the second surface of the second mold film is opposite the first surface of the second mold film in the first direction; and
a protective film covering the second surface of the bridge die and the second surface of the second mold film.

13. The semiconductor package of claim 12, wherein the second surface of the bridge die and the second surface of the second mold film are coplanar with each other.

14. The semiconductor package of claim 12, wherein the bridge die includes a first side surface, a second side surface, a third side surface, and fourth side surface, wherein the first side surface and the second side surface are opposite to each other in the second direction, and the third side surface and the fourth side surface are opposite to each other in a third direction,
wherein the second mold film covers the first side surface, the second side surface, the third side surface, and the fourth side surface of the bridge die.

15. The semiconductor package of claim 12, further comprising a heat path block (HPB) disposed on the second redistribution layer,
wherein the HPB overlaps each of the first semiconductor chip and the second semiconductor chip in the first direction.

16. The semiconductor package of claim 12, wherein a length in the second direction of the protective film is equal to a sum of a length in the second direction of the second mold film and a length in the second direction of the bridge die.

17. The semiconductor package of claim 12, wherein with respect to the lower surface of the first redistribution layer, the second surface of the bridge die and the second surface of the second mold film form a step.

18. The semiconductor package of claim 12, wherein the bridge die is surrounded by the second mold film and the protective film.

19. A semiconductor package comprising:
a redistribution layer including an upper surface and a lower surface opposite to each other in a first direction;
a semiconductor chip disposed on the upper surface of the redistribution layer;
a bridge die disposed on the lower surface of the redistribution layer, and electrically connected to the semiconductor chip, wherein the bridge die includes a first surface, a second surface opposite to the first surface, and a plurality of side surfaces connecting the first surface and the second surface to each other, wherein the first surface faces the semiconductor chip;
a mold film disposed on the plurality of side surfaces of the bridge die; and
a protective film disposed on the second surface of the bridge die.

20. The semiconductor package of claim 19, wherein the bridge die is enclosed by both the protective film and the mold film.
